(19) United States
(12) Patent Application Publication
(10) Pub. No.: US 2013/0223657 A1
(43) Pub. Date: Aug. 29, 2013

(54) ELECTRONIC DEVICE

(71) Applicants: Yasuharu Onishi, Kanagawa (JP); Yuichiro Kishinami, Kanagawa (JP); Shigeo Satou, Kanagawa (JP); Jun Kuroda, Kanagawa (JP); Yukio Murata, Kanagawa (JP); Motoyoshi Komoda, Kanagawa (JP); Nobuhiro Kawashima, Kanagawa (JP); Tatsuya Uchikawa, Kanagawa (JP)

(72) Inventors: Yasuharu Onishi, Kanagawa (JP); Yuichiro Kishinami, Kanagawa (JP); Shigeo Satou, Kanagawa (JP); Jun Kuroda, Kanagawa (JP); Yukio Murata, Kanagawa (JP); Motoyoshi Komoda, Kanagawa (JP); Nobuhiro Kawashima, Kanagawa (JP); Tatsuya Uchikawa, Kanagawa (JP)

(73) Assignee: NEC CASIO MOBILE COMMUNICATIONS, LTD., Kanagawa (JP)

(21) Appl. No.: 13/823,491

(22) PCT Filed: Sep. 14, 2011
(86) PCT No.: PCT/JP2011/005164

§ 371 Date: May 14, 2013

(30) Foreign Application Priority Data
Nov. 1, 2010 (JP) 2010-245673

(51) Int. Cl. H01L 41/053; G01S 15/08

(52) U.S. Cl. CPC H01L 41/053; G01S 15/08
USPC 381/190; 310/334; 367/99

(57) ABSTRACT

An electronic device (100) includes a housing (110) and an oscillator (200) that is provided inside the housing (110), wherein the oscillator (200) includes a piezoelectric element (210) and a first elastic member (220) that binds one surface of the piezoelectric element (210), and wherein the housing (110) includes a support section (111) that protrudes inside and supports the oscillator (200). Since the housing (110) itself is used as a support body, it is possible to reduce the size and weight of the electronic device (100).

### TECHNICAL FIELD

The present invention relates to an electronic device that uses an oscillator.

### BACKGROUND ART

A thin and stylish mobile phone has been actively developed. Accordingly, it is necessary to provide an electro acoustic transducer mounted in an electronic device such as a mobile phone, which is thin in thickness and provides a high sound quality. In the related art, as the electro acoustic transducer mounted in the mobile phone or the like, an electrodynamic electro acoustic transducer has been used. In the electrodynamic electro acoustic transducer, a magnetic circuit is used as a drive source.

Thus, the thickness of the electrodynamic electro acoustic transducer has a limit of about 3 mm. Hence, in recent years, a thin piezoelectric electro acoustic transducer has been actively developed, in place of the electrodynamic electro acoustic transducer.

Recently, various techniques have been proposed as the above-mentioned electro acoustic transducer (Patent Document 1).

### RELATED DOCUMENT

### Patent Document

[Patent Document 1] Japanese Unexamined Utility Model Registration Publication NO. S58-109397

### DISCLOSURE OF THE INVENTION

The piezoelectric electro acoustic transducer uses expansion and contraction of piezoelectric ceramics as a drive source. Thus, it is possible to reduce the thickness of the drive source. Thus, it is possible to set the thickness of the electro acoustic transducer to equal to or less than 1 mm.

On the other hand, in the piezoelectric electro acoustic transducer, it is necessary to form a support body that supports a piezoelectric element into a shape with a high strength. Thus, it is necessary to provide the support body of a large thickness inside a housing. In this case, the thickness of the electro acoustic transducer is increased.

In order to solve the above-mentioned problem, an object of the invention is to provide a small and light electronic device.

In one embodiment, there is provided an electronic device comprising: a housing; and an oscillator that is provided inside the housing, wherein the oscillator includes a piezoelectric element, and a first elastic member that binds one surface of the piezoelectric element, and wherein the housing includes a support section that protrudes inside and supports the oscillator.

In the electronic device of the invention, the housing is used as a support body of the oscillator. Since the housing itself is used as the support body of the oscillator, it is possible to realize a small and light electronic device.

### BRIEF DESCRIPTION OF THE DRAWINGS

The above and other objects, advantages and features of the present invention will be more apparent from the following description of certain preferred embodiments taken in conjunction with the accompanying drawings.

FIG. 1 is a longitudinal sectional side view schematically illustrating an internal structure of an electronic device according to an embodiment of the invention.

FIG. 2 is a longitudinal sectional side view schematically illustrating an oscillator of an electronic device.

FIG. 3 is an exploded perspective view illustrating an assembly structure of an oscillator.

FIG. 4 is a longitudinal sectional side view schematically illustrating an internal structure of an electronic device according to a modification example.

FIG. 5 is a longitudinal sectional side view schematically illustrating an internal structure of an electronic device according to another modification example.

### DESCRIPTION OF EMBODIMENTS

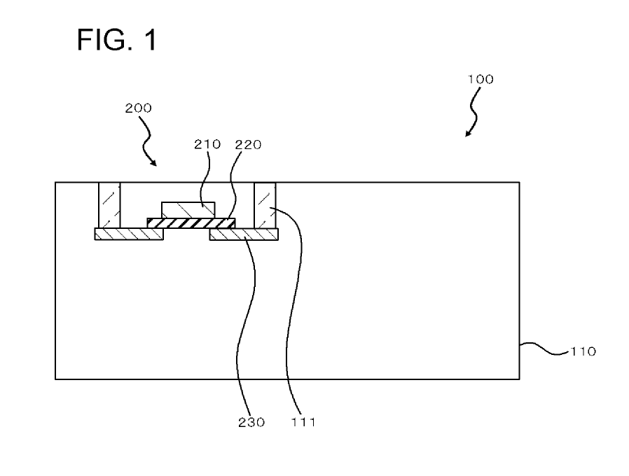

An embodiment of the invention will be described with reference to FIGS. 1 to 3. An electronic device 100 of the present embodiment includes a housing 110 and an oscillator 200, as shown in FIG. 1. The oscillator 200 includes a piezoelectric element 210, and a first elastic member 220 that binds one surface of the piezoelectric element 210. The housing 110 includes a support section 111 that protrudes inside and supports the oscillator 200.

More specifically, the electronic device 100 outputs sound waves of an audible range by the oscillator 200 that includes the above-mentioned piezoelectric element 210 and first elastic member 220, for example. Further, the electronic device 100 outputs ultrasonic waves of a frequency of equal to or higher than 20 kHz, by the oscillator 200 that includes the piezoelectric element 210 and the first elastic member 220. The electronic device 100 is a mobile phone terminal, for example.

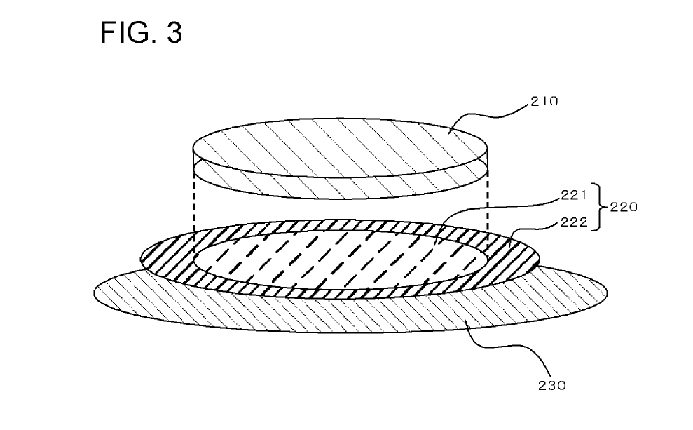

The piezoelectric element 210 has a flat plate shape. Further, as shown in FIG. 3, the piezoelectric element 210 has a circular planar shape. The planar shape of the piezoelectric element 210 is not limited to the circular shape, and may be a polygonal shape or the like, for example.

The piezoelectric element 210 is bound to the one surface of the first elastic member 220. Here, the one surface of the first elastic member 220 represents a surface among the surfaces of the first elastic member 220 that faces a surface of the housing 110 that supports the oscillator 200.

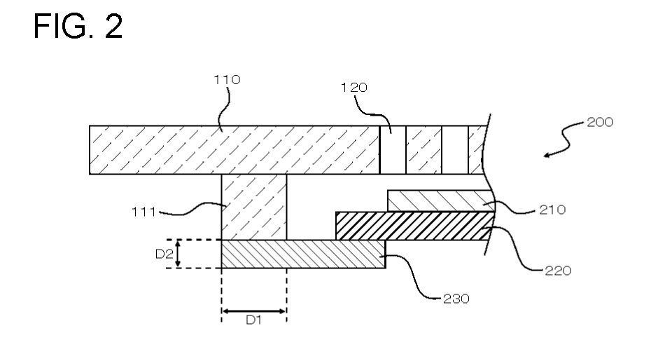

As shown in FIG. 2, a sound hole 120 is formed in a portion of the housing 110 that faces the piezoelectric element 210. For example, a plurality of sound holes 120 may be provided. The housing 110 includes the support section 111 that protrudes inside. The support section 111 is provided to be integrated with a main part of the housing 110, for example. Further, the support section 111 may be provided to be separated from the main part of the housing 110.

Further, as shown in FIG. 1, the housing 110 is formed in a box shape. In the housing 110, the plate thickness of the box shaped portion and the plate thickness of the support section 111 may be the same or different from each other.

The oscillator 200 includes a second elastic member 230. The second elastic member 230 supports the outer peripheral portion of the first elastic member 220. Further, the second elastic member 230 is supported by the support section 111.

In the present embodiment, the first elastic member 220 has a disk shape. Further, the shape of the first elastic member 220 is not limited to the disk shape, and may be a polygonal shape or the like, for example.

Further, in the present embodiment, the second elastic member 230 has a toric shape in which an opening is formed in a region including the center. The shape of the second elastic member 230 is not limited to the toric shape, and may be a polygonal shape or the like, for example.

The first elastic member 220 is formed of phosphor bronze or the like, for example. Further, the second elastic member 230 is formed of a PET film or the like, for example.

The support section 111 has a tubular shape that extends inside from the main part of the housing 110, for example. In the electronic device 100 of the present embodiment, as shown in FIG. 1, an outer peripheral portion of the toric second elastic member 230 is mounted on a lower surface (in the figure) of the tubular support section 111. As shown in FIG. 3, the outer peripheral portion of the toric first elastic member 220 is supported on an upper surface of an inner peripheral portion of the second elastic member 230.

The first elastic member 220 is supported on the second elastic member 230 to cover the opening provided in the second elastic member 230. The piezoelectric element 210 of a disk shape is mounted on an upper surface of the first elastic member 220.

In the electronic device 100 of the present embodiment, any one of upper and lower main surfaces of the piezoelectric element 210 is bound by the first elastic member 220. Further, as shown in FIG. 3, the first elastic member 220 includes a seat section 221 that binds the piezoelectric element 210, and a non-binding section 222 that is formed by an outer peripheral portion of the seat section 221 and does not bind the piezoelectric element 210. The non-binding section 222 is connected to the housing 110 through the second elastic member 230. In this way, the oscillator 200 that is an electro acoustic transducer is formed.

The second elastic member 230 is formed of a material having low rigidity with respect to the housing 110. The modulus of longitudinal elasticity (Young's modulus) of the material used in the second elastic member 230 is equal to or less than 1/10 compared with the material of the housing 110.

Further, in FIG. 2, the thickness of the second elastic member 230 in a vibration direction of the oscillator 200 is set to D2, and the thickness of the support section 111 in a planar direction perpendicular to the vibration direction is set to D1. Here, it is preferable that D2 be equal to or less than ⅕ of D1.

As described above, the rigidity of the second elastic member 230 is lower than that of the housing 110 that is a support body. Thus, it is possible to absorb unnecessary vibration other than vibration in the thickness direction converted into sound waves, by the second elastic member 230. Here, the unnecessary vibration represents vibration or the like in the planar direction perpendicular to the thickness direction, for example.

Further, it is possible to integrally form the first elastic member 220 and the second elastic member 230. Thus, it is possible to easily manufacture the oscillator 200 according to the present embodiment.

In the invention, as described above, the housing 110 of the electronic device 100 is used as the support body of the oscillator 200. That is, the electronic device 100 has a configuration in which the piezoelectric element 210, the first elastic member 220 and the second elastic member 230 are directly connected to the housing 110. Here, the oscillator 200 includes the piezoelectric element 210, the first elastic member 220, the second elastic member 230, and the housing 110.

Any one of the upper and lower main surfaces of the piezoelectric element 210 is bound by the first elastic member 220. The first elastic member 220 includes the seat section 221 that binds the piezoelectric element 210, and the non-binding section 222 that is formed by the outer peripheral portion of the seat section 221 and does not bind the piezoelectric element 210. The non-binding section 222 is connected to the housing 110 through the second elastic member 230. In this way, the oscillator 200 is formed.

In the piezoelectric oscillator in the related art, the support body that supports the piezoelectric element is provided, in addition to the housing.

Further, the piezoelectric oscillator includes high vibration energy in the resonance frequency. Thus, in a case where vibration from the piezoelectric element propagates to the housing of the electronic device through the support body that supports the piezoelectric element, there is a problem in that the housing of the electronic device is abnormally vibrated to thereby cause abnormal noise. Accordingly, in the piezoelectric oscillator in the related art, in order to suppress unnecessary vibration generated from the piezoelectric element from propagating to the housing, the thickness of the support body is increased.

Thus, it is difficult to achieve a small and light electronic device. Further, it is necessary to design the electronic device according to the size of the oscillator, which causes restriction in design of the electronic device.

On the other hand, in the electronic device 100 according to the present embodiment, the housing 110 itself is used as the support body that supports the piezoelectric element 210. That is, the piezoelectric element 210 is connected to the housing 110 through the first elastic member 220 and the second elastic member 230. Thus, it is not necessary to provide the support body that supports the piezoelectric element 210, in addition to the housing 110. Accordingly, it is possible to achieve a small and light electronic device. Further, it is possible to enhance the degree of design freedom of the electronic device.

Further, in the electronic device 100 according to the present embodiment, the modulus of longitudinal elasticity (Young's modulus) of the second elastic member 230 that is connected to the housing 110 is equal to or less than 1/10 compared with the housing 110. Further, the thickness D2 of the second elastic member 230 is equal to or less than ⅕ of the thickness D1 of the support section 111. Thus, the energy (stress) due to vibration is concentrated on the second elastic member 230 from the viewpoint of mechanical impedance. Therefore, it is possible to suppress unnecessary vibration generated from the piezoelectric element from propagating to the housing.

The invention is not limited to the present embodiment, and various modifications are allowed in the range without departing from the spirit of the invention. For example, in the above embodiment, the mobile phone terminal is used as the electronic device 100. However, it is possible to realize, as the electronic device 100, a sonar (not shown) or the like that includes an oscillation drive unit that makes the oscillator 200 that includes the piezoelectric element 210, the first elastic member 220 and the second elastic member 230, output ultrasonic waves, an ultrasonic wave detecting unit that detects the ultrasonic waves that are oscillated from the oscillator 200 and are reflected from a measurement target, and a distance measuring unit that calculates the distance to the measurement target based on the detected ultrasonic waves.

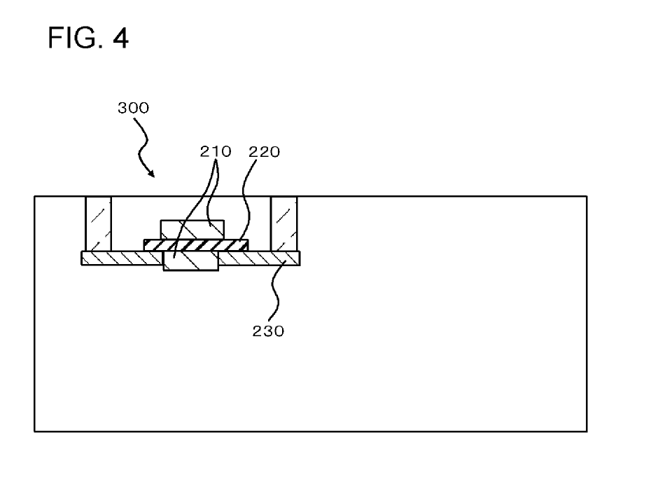

Further, in the above-described embodiment, an example in which the monomorph oscillator 200 in which one piezoelectric element 210 is mounted on one surface of the first elastic member 220 has been described. However, as shown in FIG. 4, it is possible to realize a bimorph oscillator 300 in which two piezoelectric elements 210 bind both main surfaces of the first elastic member 220.

Further, in the above embodiment, as shown in FIG. 1, the outer peripheral portion of the disk-shaped first elastic member 220 is supported on the upper surface of the inner peripheral portion of the second elastic member 230. Further, the disk-shaped piezoelectric element 210 is mounted on the upper surface of the first elastic member 220.

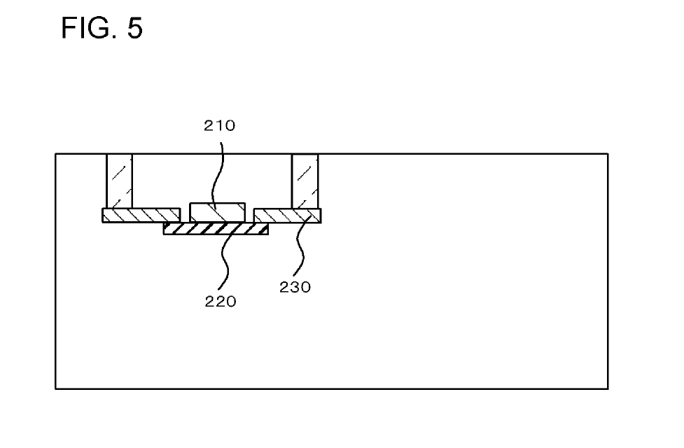

However, as shown in FIG. 5, the outer peripheral portion of the disk-shaped first elastic member 220 may be supported on the lower surface of the inner peripheral portion of the second elastic member 230. Further, the disk-shaped piezoelectric element 210 may be mounted on the lower surface of the first elastic member 220 (not shown).

Further, in the above embodiment, the planar shape of the main surface of the piezoelectric element 210 is circular, but the planar shape of the main surface of the piezoelectric element 210 may be rectangular (not shown).

The above-described embodiment and a plurality of modification examples may be combined with each other in a range where the contents thereof do not conflict with each other. Further, in the above-described embodiment and modification examples, structures or the like of the respective sections have been specifically described, but the structures or the like may be changed in a range where the invention is satisfied.

This application is based on Japanese patent application NO. 2010-245673, filed on Nov. 1, 2010, the content of which is incorporated hereinto by reference.

1. An electronic device comprising:
a housing; and
an oscillator that is provided inside the housing,
wherein the oscillator includes
a piezoelectric element, and
a first elastic member that binds one surface of the piezoelectric element, and
wherein the housing includes a support section that protrudes inside and supports the oscillator.

2. The electronic device according to claim 1, further comprising:
a second elastic member that supports an outer peripheral portion of the first elastic member and is supported by the support section.

3. The electronic device according to claim 2,
wherein the Young's modulus of the second elastic member is equal to or less than 1/10 of that of the housing.

4. The electronic device according to claim 2,
wherein the thickness of the second elastic member in a vibration direction of the oscillator is equal to or less than ⅕ of the thickness of the support section in a planar direction perpendicular to the vibration direction.

5. The electronic device according to claim 4,
wherein the support section is provided to be integrated with a main part of the housing.

6. The electronic device according to claim 1, further comprising:
an oscillator drive unit that makes the oscillator output sound waves of an audible range.

7. The electronic device according to claim 1, further comprising:
an oscillator drive unit that makes the oscillator output ultrasonic waves;
an ultrasonic wave detecting unit that detects the ultrasonic waves that are oscillated from the piezoelectric element and are reflected from a measurement target; and
a distance measuring unit that calculates the distance to the measurement target based on the detected ultrasonic waves.

8. The electronic device according to claim 1,
wherein two piezoelectric elements bind both main surfaces of the first elastic member.

9. The electronic device according to claim 1,
wherein the oscillator outputs the ultrasonic waves having a frequency of equal to or higher than 20 kHz.
